(19) United States
(12) Patent Application Publication
(10) Pub. No.: US 2025/0167509 A1
(43) Pub. Date: May 22, 2025

(54) OPTICAL RECEPTACLE AND OPTICAL MODULE

(71) Applicant: Enplas Corporation, Saitama (JP)

(72) Inventors: Yuki SAITO, Saitama (JP); Takayoshi SUGANUMA, Saitama (JP)

(21) Appl. No.: 18/841,494

(22) PCT Filed: Feb. 28, 2023
(86) PCT No.: PCT/JP2023/007375

§ 371 Date: Aug. 26, 2024

(30) Foreign Application Priority Data
Feb. 28, 2022 (JP) 2022-030192

(51) Int. Cl. H01S 5/02251

(52) U.S. Cl. CPC H01S 5/02251

(57) ABSTRACT

This optical receptacle comprises a first optical surface (121), a second optical surface (122) and a diffraction portion (123) which is for diffracting at least a part of the light that has entered at the first optical surface toward the optical transmission body as n-order diffracted light. The diffraction portion (123) satisfies formula (1) sinθr=(1/N)×{N×sinθi−n×(λ/Λ)} and formula (2) 70°<θr+θi<110°, where X represents the wavelength of the light incident on the first optical surface, N represents the refractive index of a medium in which the light incident on the diffraction portion travels, A represents the period of the blazed shape, θi represents the angle of incidence of the light incident on the first optical surface with respect to the diffraction portion, and Or represents the reflection diffraction angle with respect to the optical transmission body.

### TECHNICAL FIELD

The present invention relates to an optical receptacle and an optical module.

### BACKGROUND ART

Conventionally, in optical communications using an optical transmission member such as an optical fiber, an optical waveguide, and/or the like, an optical module including a light emitting element such as a surface-emitting laser (e.g., a Vertical Cavity Surface Emitting Laser (VCSEL)) has been used. The optical module includes one or more photoelectric conversion elements (light emitting elements or light receiving elements) and an optical receptacle (coupling lens) for transmission, reception, or transmission and reception.

Further, from the viewpoint of safety measures, the optical module for optical communication detects part of the light emitted from the optical receptacle for transmission to monitor whether or not the optical module operates properly (for example, refer to Patent Literature (hereinafter, referred to as “PTL”) 1).

PTL 1 describes a VCSEL assembly including a VCSEL, a prism, and a photodetector. The prism has an incidence surface, a reflective surface, and an emission surface. A part of the reflective surface is provided with an identification section including a first surface.

Light emitted by the VCSEL is incident on the prism at the incidence surface and reaches the reflective surface. A part of the light reaching the reflective surface is reflected on the reflective surface toward an optical fiber as signal light, and another part of the light is reflected on the first surface toward the photodetector as monitor light.

### CITATION LIST

### Patent Literature

PTL 1
US Patent Application Publication No. 2016/0172821

### SUMMARY OF INVENTION

### Technical Problem

As described above, in the VCSEL assembly described in PTL 1, the signal light and the monitor light are separated from each other by changing the tilt angles of the reflective surface and the first surface. Therefore, when a molding defect occurs when the prism is molded, the shape of a spot of the signal light may be distorted. When the shape of the spot is distorted, the optical coupling efficiency may be remarkably lowered due to the positional deviation between the prism and the optical fiber.

Therefore, an object of the present invention is to provide an optical receptacle capable of suppressing a decrease in optical coupling efficiency even when a positional deviation occurs between the optical receptacle and the optical transmission member. Another object of the present invention is to provide an optical module including the optical receptacle.

### Solution to Problem

An optical receptacle of the present invention is an optical receptacle that is disposed between an optical transmission member and a photoelectric conversion device including a light emitting element, the optical receptacle being configured to optically connect the light emitting element and the optical transmission member to each other, the optical receptacle including: a first optical surface for allowing incidence of light emitted by the light emitting element; a second optical surface for causing, to be emitted toward the optical transmission member, the light incident on the first optical surface and traveling inside the optical receptacle; and a diffraction portion including a blaze shape and configured to diffract at least a part of the light incident on the first optical surface as n-th order diffracted light (n=−1, −2, or −3) toward the optical transmission member, in which the diffraction portion satisfies following Expressions 1 and 2 when a wavelength of the light incident on the first optical surface is denoted by λ, a refractive index of a medium through which the light incident on the diffraction portion travels is denoted by N, a period of the blaze shape is denoted by Λ, an incidence angle at which the light incident on the first optical surface is incident on the diffraction portion is denoted by θi, and a reflection diffraction angle to the optical transmission member is denoted by θr:

$$\begin{matrix}[ 1 ] & \\ sin θ r = ( 1 / N ) \times \{ N \times sin θ i - n \times ( λ \times Λ ) \} ; and & ( Expression 1 )\end{matrix}$$

$$\begin{matrix}[ 2 ] & \\ 70 ° \leq θ r + θ i \leq 110 ° . & ( Expression 2 )\end{matrix}$$

An optical module according to the present invention is an optical module including: a photoelectric conversion device including a light emitting element; and an optical receptacle disposed between the photoelectric conversion device and an optical transmission member and configured to optically connect the light emitting element and the optical transmission member to each other, in which the optical receptacle includes: a first optical surface for allowing incidence of light emitted by the light emitting element, a first optical surface for allowing incidence of light emitted by the light emitting element, a second optical surface for causing, to be emitted toward the optical transmission member, the light incident on the first optical surface and traveling inside the optical receptacle, and a diffraction portion including a blaze shape and configured to diffract at least a part of the light incident on the first optical surface as n-th order diffracted light (n=−1, −2, or −3) toward the optical transmission member, the diffraction portion satisfies following Expressions 1 and 4 when a wavelength of the light incident on the first optical surface is denoted by λ, a refractive index of a medium through which the light incident on the diffraction portion travels is denoted by N, a period of the blaze shape is denoted by Λ, an incidence angle at which the light incident on the first optical surface is incident on the diffraction portion is denoted by θi, and a reflection diffraction angle to the optical transmission member is denoted by θr, and an angle formed by a first straight line and a second straight line is identical to a sum of the incidence angle and the reflection diffraction angle, the first straight line connecting a center point of the light emitting element and an arrival point at the diffraction portion where a center of a light flux from the light emitting element arrives, the second straight line connecting the arrival point and a center point at an end portion of the optical transmission member:

$$\begin{matrix}[ 1 ] & \\ sin θ r = ( 1 / N ) \times \{ N \times sin θ i - n \times ( λ \times Λ ) \} ; and & ( Expression 1 )\end{matrix}$$

$$\begin{matrix}[ 4 ] & \\ 36 ° \leq θ i \leq 89 ° . & ( Expression 4 )\end{matrix}$$

### Advantageous Effects of Invention

The optical receptacle of the present invention can suppress a decrease in optical coupling efficiency even when a positional deviation occurs between the optical receptacle and the optical transmission member.

### BRIEF DESCRIPTION OF DRAWINGS

FIG. 1 illustrates a configuration of an optical module according to Embodiment 1;

FIGS. 2A and 2B illustrate the configuration of an optical receptacle according to Embodiment 1;

FIGS. 3A to 3D illustrate a configuration of the optical receptacle according to Embodiment 1;

FIGS. 4A and 4B are graphs illustrating measurement results of optical coupling efficiency;

FIGS. 5A and 5B illustrate a configuration of an optical receptacle according to Embodiment 2;

FIGS. 6A and 6D illustrate the configuration of the optical receptacle according to Embodiment 2;

FIG. 7 is a perspective view of an optical receptacle according to Embodiment 3;

FIGS. 8A and 8B illustrate the configuration of the optical receptacle according to Embodiment 3;

FIGS. 9A to 9D illustrate the configuration of the optical receptacle according to Embodiment 3;

FIG. 10 is a perspective view of an optical receptacle according to Embodiment 4;

FIGS. 11A and 11B illustrate the configuration of the optical receptacle according to Embodiment 4;

FIGS. 12A and 12B illustrate the configuration of the optical receptacle according to Embodiment 4;

FIGS. 13A and 13B illustrate the configuration of the optical receptacle according to Embodiment 4;

FIGS. 14A and 14B illustrate a configuration of an optical receptacle according to Embodiment 5;

FIGS. 15A to 15D illustrate the configuration of the optical receptacle according to Embodiment 5;

FIG. 16 illustrate a configuration of an optical receptacle according to Embodiment 6;

FIGS. 17A and 17B illustrate the configuration of the optical receptacle according to Embodiment 6;

FIGS. 18A and 18B illustrate the configuration of the optical receptacle according to Embodiment 6;

FIGS. 19A and 19B illustrate the configuration of the optical receptacle according to Embodiment 6;

FIGS. 20A and 20B illustrate a configuration of an optical receptacle according to Embodiment 7;

FIGS. 21A and 21B are graphs illustrating a relation between a blaze shape and diffraction efficiency of the optical receptacle according to Embodiment 7; and

FIGS. 22A and 22B are graphs illustrating the relation between the blaze shape and the diffraction efficiency of the optical receptacle according to Embodiment 7.

Hereinafter, an optical receptacle and an optical module according to one embodiment of the present invention will be described in detail with reference to the drawings.

### Embodiment 1

### (Configuration of Optical Module)

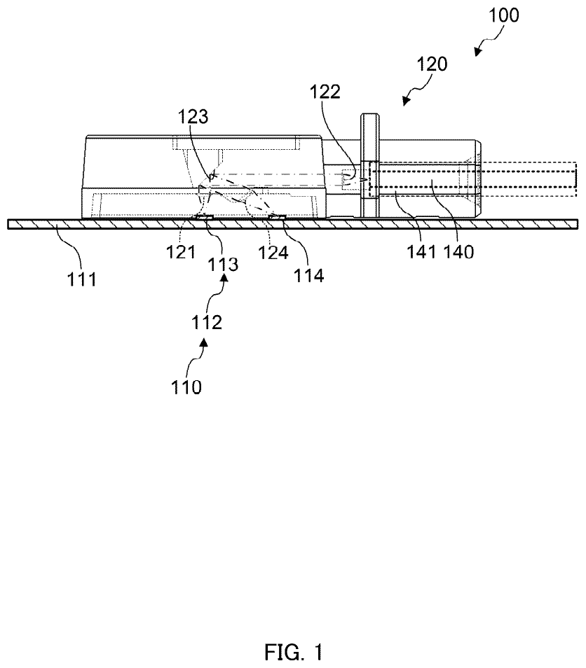

FIG. 1 illustrates a configuration of optical module 100 according to Embodiment 1 of the present invention.

As illustrated in FIG. 1, optical module 100 includes photoelectric conversion device 110 including photoelectric conversion element 112 and optical receptacle 120. Optical module 100 is used by connecting optical transmission member 140 to optical receptacle 120. Optical module 100 according to the present embodiment is an optical module for transmission.

Photoelectric conversion device 110 includes substrate 111 and photoelectric conversion element 112.

Photoelectric conversion element 112 and optical receptacle 120 are disposed on substrate 111. Substrate 111 may be provided with a substrate protrusion (not illustrated) corresponding to a substrate recessed portion (not illustrated) of optical receptacle 120. By fitting the substrate protrusion into the substrate recessed portion, optical receptacle 120 can be disposed at a predetermined position with respect to photoelectric conversion element 112 on substrate 111. The material of substrate 111 is not particularly limited. Examples of substrate 111 include a glass composite substrate and a glass epoxy substrate.

Photoelectric conversion element 112 includes light emitting element 113 and detection element 114, and is disposed on substrate 111. In the present embodiment, photoelectric conversion device 110 includes one light emitting element 113 and one detection element 114 as photoelectric conversion element 112. Light emitting element 113 is, for example, a vertical cavity surface emitting laser (VCSEL). Wavelength k of light emitted by light emitting element 113 is in the range of 0.85 to 1.67 m (near infrared rays). When wavelength k of the light emitted by light emitting element 113 is within this range, the light can be transmitted with low loss in multi-mode or single-mode optical transmission member 140. Detection element 114 is, for example, a photodetector. In the present embodiment, the light emitting surface of light emitting element 113 and the light receiving surface of detection element 114 are disposed to be parallel to each other. Note that a device including light emitting element 113 and another device including detection element 114 may be separately configured.

Optical receptacle 120 is disposed on substrate 111 so as to face photoelectric conversion element 112. Optical receptacle 120 optically couples the light emitting surface of photoelectric conversion element 112 (light emitting element 113) and the end surface of optical transmission member 140 when disposed between photoelectric conversion element 112 and optical transmission member 140. In the present embodiment, optical receptacle 120 emits a part of the light emitted by photoelectric conversion element 112 (light emitting element 113) toward the end surface of optical transmission member 140, and emits another part of the light toward detection element 114. The configuration of optical receptacle 120 will be described in detail separately.

The type of optical transmission member 140 is not particularly limited. Examples of the type of optical transmission member 140 include an optical fiber, an optical waveguide, and the like. Optical transmission member 140 is connected to optical receptacle 120 via ferrule 141. In the present embodiment, optical transmission member 140 is an optical fiber. In addition, the optical fiber may be a single mode optical fiber or a multi-mode optical fiber. When optical transmission member 140 is an optical fiber, optical transmission member 140 includes a core portion and a cladding portion.

### (Configuration of Optical Receptacle)

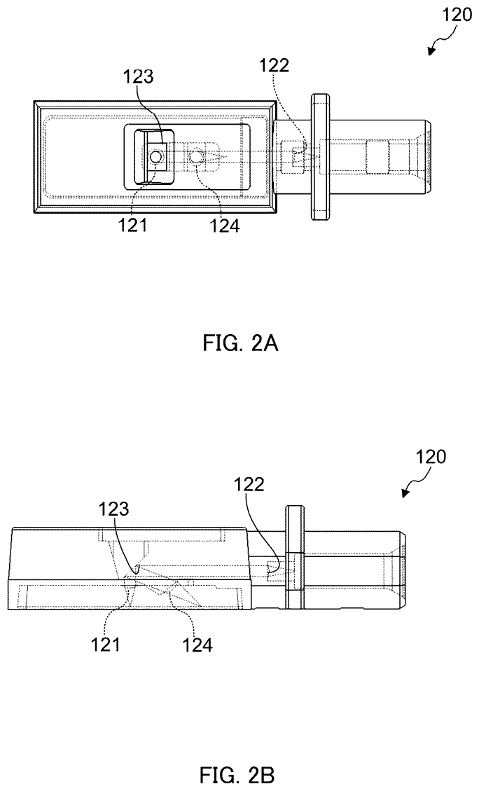

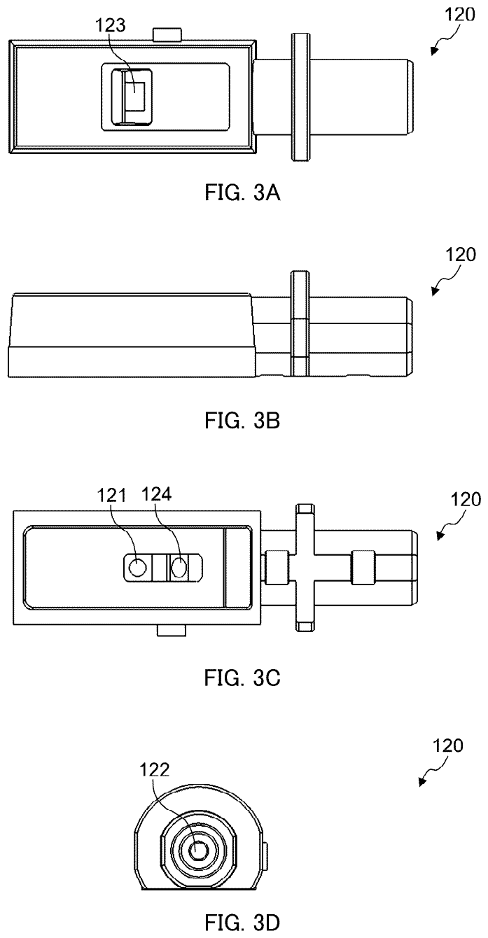

FIG. 2A is a plan view of optical receptacle 120, and FIG. 2B is a front view of optical receptacle 120. FIG. 3A is a plan view of optical receptacle 120, FIG. 3B is a front view of optical receptacle 120, FIG. 3C is a bottom view of optical receptacle 120, and FIG. 3D is a side view of optical receptacle 120. Note that FIG. 2A corresponds to FIG. 3A, and FIG. 2B corresponds to FIG. 3B. In FIGS. 2A and 2B, the interior configuration and the optical path are illustrated in dotted lines.

As illustrated in FIGS. 2A, 2B, and 3A to 3D, optical receptacle 120 is a substantially rectangular parallelepiped-shaped member. Optical receptacle 120 includes first optical surface 121, second optical surface 122, and diffraction portion 123. In the present embodiment, optical receptacle 120 further includes fourth optical surface 124.

Optical receptacle 120 is formed of a material that allows light having a wavelength used for optical communication to pass therethrough. Exemplary materials for optical receptacle 120 include transparent resins such as polyether imides (PEI) (e.g., ULTEM (registered trademark)) and cyclic olefinic resins and glasses. Optical receptacle 120 can be manufactured, for example, by injection molding. It is preferable that refractive indices N of resins used for optical receptacle 120 be in the range of 1.44 to 1.65, and refractive indices N of glasses used for optical receptacle 120 be in the range of 1.4 to 1.9. It is preferable that first optical surface 121, second optical surface 122, and diffraction portion 123 of optical receptacle 120 be formed integrally. This can reduce the number of parts.

First optical surface 121 is an optical surface that allows, to enter the inside of optical receptacle 120, light emitted by photoelectric conversion element 112 (light emitting element 113). The shape of first optical surface 121 is not particularly limited. The shape of first optical surface 121 may be a flat surface, a convex lens surface convex toward light emitting element 113, or a concave lens surface concave toward light emitting element 113. In the present embodiment, the shape of first optical surface 121 is a convex lens surface that is convex toward light emitting element 113. The shape of first optical surface 121 in plan view is circular. It is preferable that the central axis of first optical surface 121 be perpendicular to the light emitting surface of light emitting element 113. It is preferable that the central axis of first optical surface 121 coincide with the optical axis of the light emitted by light emitting element 113. It is preferable that wavelength k of the light incident on first optical surface 121 be in the range of 0.85 to 1.60 m.

Second optical surface 122 is an optical surface that causes a part of the light incident on first optical surface 121 (signal light to be described later) to be emitted toward the end surface of optical transmission member 140. The shape of second optical surface 122 is not particularly limited. The shape of second optical surface 122 may be a flat surface, a convex lens surface convex toward the end surface of optical transmission member 140, or a concave lens surface concave toward optical transmission member 140. In the present embodiment, the shape of second optical surface 122 is a convex lens surface that is convex toward the end surface of optical transmission member 140. It is preferable that the central axis of second optical surface 122 coincide with the optical axis of the light incident on optical transmission member 140.

Diffraction portion 123 is a reflective diffraction grating that diffracts at least a part of the light incident on first optical surface 121 toward optical transmission member 140 as n-th order diffracted light (n=−1, −2, or −3) (signal light), and diffracts at least another part of the light toward detection element 114 as m-th order diffracted light (m is an integer other than n) (monitor light). The n-th order diffracted light (n=−1, −2, or −3) may be −1st order diffracted light, may be −2nd order diffracted light, or may be −3rd order diffracted light. The m-th order diffracted light (m is an integer other than n) may be the (n+1)-th order diffracted light, or may be the (n−1)-th order diffracted light, or may be the (n−2)-th order diffracted light, or may be the diffracted light of another order as long as it is other than the n-th order diffracted light (n is an integer). In the present embodiment, the n-th order diffracted light is −3rd order diffracted light, and the m-th order diffracted light is 0th order diffracted light.

Diffraction portion 123 diffracts the n-th order diffracted light (−3rd order diffracted light in the present embodiment) and the m-th order diffracted light (0th order diffracted light in the present embodiment) in respective different directions in the first imaginary plane including the optical axis of the light emitted by light emitting element 113 and incident on first optical surface 121. Examples of diffraction portion 123 include a diffraction grating. The angle formed between the optical axis of the n-th order diffracted light and the optical axis of the m-th order diffracted light in the first imaginary plane is not particularly limited. The angle formed between the optical axis of the n-th order diffracted light and the optical axis of the m-th order diffracted light in the first imaginary plane is in the range of 10 to 90 degrees. When the angle is within the above range, the signal light and the monitor light can be separated.

Diffraction portion 123 has a plurality of blaze shapes (serrations). The number of blaze shapes is appropriately set in accordance with the diffraction angles of the n-th order diffracted light and the m-th order diffracted light. For example, when the diffraction grating is disposed on a surface that reflects light by 780 and the diffraction angles of the 0th order diffracted light and the −3rd order diffracted light are set to 12°, the number of blaze shapes in a region of a square with sides of 0.3 mm is in the range of about 40 to 50. The sizes of the blaze shapes may be the same size or different sizes. The height of the blaze shape is appropriately set depending on the intensity ratio of the diffracted light. In the present embodiment, 5% of the 0th order diffracted light is set with respect to 55% of the −3rd order diffracted light, the height (depth) of the blaze shapes is within a range of from 1,200 to 1,300 nm. In the present embodiment, a plurality of blaze shapes are disposed at positions where the light incident on first optical surface 121 reaches. That is, in the present embodiment, diffraction portion 123 is composed of blaze shapes.

Diffraction portion 123 satisfies following Expressions 1 and 2 when the wavelength of the light incident on first optical surface 121 is denoted by λ, the refractive index of the medium through which the light incident on diffraction portion 123 travels is denoted by N, the period of the blaze shape is denoted by Λ, the incidence angle of the light incident on first optical surface 121 to diffraction portion 123 is denoted by θi, and the reflection diffraction angle to optical transmission member 140 is denoted by θr:

$$\begin{matrix}[ 1 ] & \\ sin θ r = ( 1 / N ) \times \{ N \times sin θ i - n \times ( λ \times Λ ) \} ; and & ( Expression 1 )\end{matrix}$$

$$\begin{matrix}[ 2 ] & \\ 70 ° \leq θ r + θ i \leq 110 ° . & ( Expression 2 )\end{matrix}$$

It is preferable that incidence angle θi satisfy following Expression 4:

$$\begin{matrix}[ 4 ] & \\ 36 ° \leq θ i \leq 89 ° . & ( Expression 4 )\end{matrix}$$

Fourth optical surface 124 is an optical surface that causes, to be emitted toward detection element 114, a part of the light incident on first optical surface 121 (the monitor light described above). Specifically, fourth optical surface 124 is an optical surface that causes, to be emitted toward detection element 114, the monitor light separated by the diffraction by diffraction portion 123. The shape of fourth optical surface 124 is not particularly limited. The shape of fourth optical surface 124 may be a flat surface, a convex lens surface convex toward the detection surface of detection element 114, or a concave lens surface concave toward the detection surface of detection element 114. In the present embodiment, the shape of fourth optical surface 124 is a convex lens surface that is convex toward optical transmission member 140. It is preferable that the central axis of fourth optical surface 124 coincide with the optical axis of the monitor light incident on detection element 114.

Next, the optical path in optical module 100 according to the present embodiment will be described. Light emitted by photoelectric conversion element 112 (light emitting element 113) enters the inside of optical receptacle 120 at first optical surface 121. At this time, the light having entered optical receptacle 120 is converted into collimated light by first optical surface 121, and travels inside optical receptacle 120. Then, the light having entered optical receptacle 120 is diffracted by diffraction portion 123 to be separated into signal light and monitor light. At this time, diffraction portion 123 directs apart of the arriving light to second optical surface 122, and directs another part of the arriving light to fourth optical surface 124. In the present embodiment, diffraction portion 123 diffracts a part of the light incident on the first optical surface toward optical transmission member 140 as −3rd order diffracted light (signal light), and diffracts another part of the light toward detection element 114 as 0th order diffracted light (monitor light).

The −3rd order diffracted light (signal light) that has reached second optical surface 122 is emitted from second optical surface 122 and reaches optical transmission member 140. It is preferable that the −3rd order diffracted light (signal light) reach a core portion instead of a cladding portion of optical transmission member (optical fiber) 140.

The 0th order diffracted light (monitor light) that has reached fourth optical surface 124 is emitted from fourth optical surface 124 and reaches detection element 114.

### (Measurement Result)

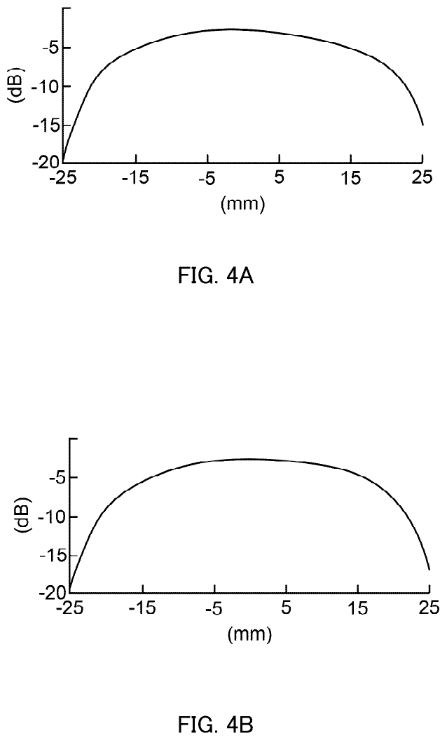

Examination was conducted on the optical coupling efficiency with respect to the distance between the optical axis of the signal light emitted from second optical surface 122 and the center of optical transmission member 140 as seen along the traveling direction of the signal light emitted from second optical surface 122 of optical receptacle 120. FIG. 4A illustrates a result of the optical coupling efficiency measured when the optical axis of the signal light and the center of optical transmission member 140 are separated in the X direction as seen along the traveling direction of the signal light, and FIG. 4B illustrates a result of the optical coupling efficiency measured when the optical axis of the signal light and the center of optical transmission member 140 are separated in the Y direction as seen along the traveling direction of the signal light. Here, the X direction means the left-right direction with respect to second optical surface 122 as seen in front view, and the Y direction means the up-down direction with respect to second optical surface 122 as seen in plan view. In FIGS. 4A and 4B, the vertical axis indicates the optical coupling efficiency, and the horizontal axis indicates the distance between the optical axis of the signal light and the center of optical transmission member 140 as seen along the traveling direction of the signal light.

As illustrated in FIGS. 4A and 4B, it can be seen that a decrease in the optical coupling efficiency can be suppressed even when the optical axis of second optical surface 122 or the central axis of optical transmission member 140 is displaced in either the X direction or the Y direction. In addition, the results are substantially symmetrical in both of the graphs illustrated in FIGS. 4A and 4B. It can thus be understood that the shape of the spot is not distorted.

### Effects

Optical receptacle 120 according to the present embodiment separates light into the signal light and the monitor light by using diffraction by diffraction portion 123. Thus, distortion of the shape of the spot is less likely to occur even when a slight molding defect occurs. Further, it is possible to suppress a decrease in the optical coupling efficiency even when optical receptacle 120 and optical transmission member 140 are displaced from each other.

In the present embodiment, the signal light diffracted by diffraction portion 123 directly reaches second optical surface 122, but may reach second optical surface 122 via another surface. In this case, the other surface may be a transmissive surface or a reflective surface. Further, in the present embodiment, the monitor light diffracted by diffraction portion 123 directly reaches fourth optical surface 124, but may reach fourth optical surface 124 via another surface. In this case, the other surface may be a transmissive surface or a reflective surface.

### Embodiment 2

Next, an optical module according to Embodiment 2 will be described. The optical module according to the present embodiment differs from the optical module according to Embodiment 1 only in the configuration of diffraction portion 223. Therefore, the same components as those of optical module 100 according to Embodiment 1 are denoted by the same reference numerals, and the description thereof is omitted.

### (Configuration of Optical Module)

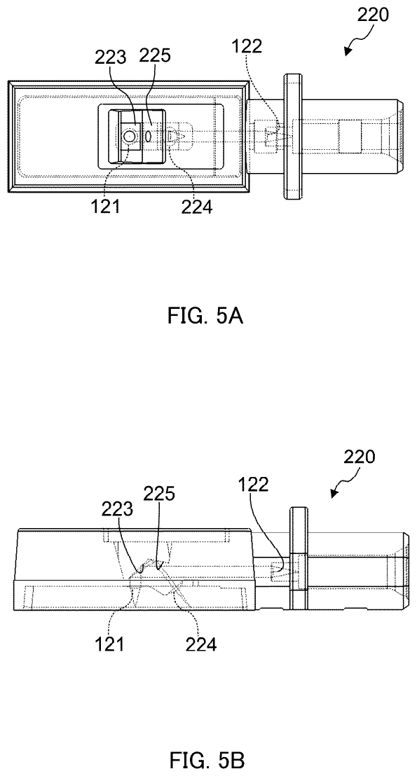

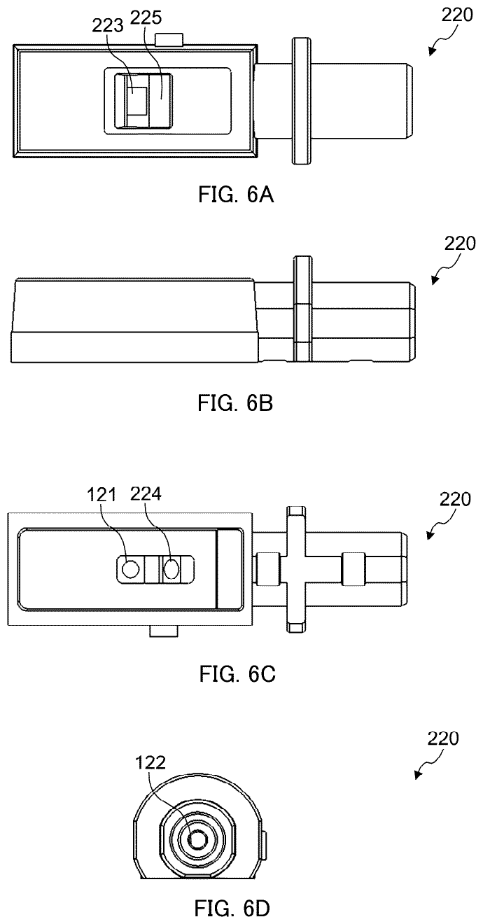

FIG. 5A is a plan view of optical receptacle 220 according to Embodiment 2, and FIG. 5B is a front view of optical receptacle 220. FIG. 6A is a plan view of optical receptacle 220, FIG. 6B is a front view of optical receptacle 220, FIG. 6C is a bottom view of optical receptacle 220, and FIG. 6D is a side view of optical receptacle 220. Note that FIG. 5A corresponds to FIG. 6A, and FIG. 5B corresponds to FIG. 6B. In FIGS. 5A and 5B, the interior configuration and the optical path are illustrated in dotted lines.

The optical module includes photoelectric conversion device 110 and optical receptacle 220. As illustrated in FIGS. 5A, 5B, and 6A to 6D, optical receptacle 220 includes first optical surface 121, second optical surface 122, and diffraction portion 223. In the present embodiment, optical receptacle 220 further includes third optical surface 225 and fourth optical surface 224. In the present embodiment, in optical receptacle 220, first optical surface 121, second optical surface 122, diffraction portion 223, third optical surface 225, and fourth optical surface 224 are integrally formed.

Diffraction portion 223 diffracts a part of the light incident on first optical surface 121 toward optical transmission member 140 as n-th order diffracted light (n=−1, −2, or −3) (signal light), and diffracts another part of the light to detection element 114 as m-th order diffracted light (m is an integer other than n) (monitor light). Diffraction portion 223 diffracts the n-th order diffracted light and the m-th order diffracted light in respective different directions in the first imaginary plane including the optical axis of the light emitted by light emitting element 113 and incident on first optical surface 121. The angle formed between the optical axis of the n-th order diffracted light and the optical axis of the m-th order diffracted light in the first imaginary plane is in the range of 10 to 90 degrees. When the angle is within the above range, the signal light and the monitor light can be separated.

Third optical surface 225 is an optical surface that reflects, toward fourth optical surface 224, the monitor light diffracted by diffraction portion 223. In the present embodiment, the shape of third optical surface 225 is a flat surface. Third optical surface 225 is an inclined surface inclined toward fourth optical surface 224 with decreasing distance to second optical surface 122.

Diffraction portion 223 satisfies following Expressions 1 and 2 when the wavelength of the light incident on first optical surface 121 is denoted by λ, the refractive index of the medium through which the light incident on diffraction portion 223 travels is denoted by N, the period of the blaze shape is denoted by Λ, the incidence angle of the light incident on first optical surface 121 to diffraction portion 223 is denoted by θi, and the reflection diffraction angle to optical transmission member 140 is denoted by θr:

$$\begin{matrix}[ 1 ] & \\ sin θ r = ( 1 / N ) \times \{ N \times sin θ i - n \times ( λ \times Λ ) \} ; and & ( Expression 1 )\end{matrix}$$

$$\begin{matrix}[ 2 ] & \\ 70 ° \leq θ r + θ i \leq 110 ° . & ( Expression 2 )\end{matrix}$$

It is preferable that incidence angle θi satisfy following Expression 4:

$$[ 4 ]$$

$$36 ° \leq θ i \leq 89 ° . \qquad ( Expression 4 )$$

Although the result is not particularly illustrated, the optical module of the present embodiment successfully suppressed a decrease in the optical coupling efficiency even when the optical axis of second optical surface 122 or the central axis of optical transmission member 140 is displaced in either of the X direction and the Y direction. Further, it was ascertained that the shape of the spot was not distorted.

### Effects

The optical module according to the present embodiment has the same effect as optical module 100 according to Embodiment 1.

### Embodiment 3

Next, an optical module according to Embodiment 3 will be described. The optical module according to the present embodiment differs from optical module 100 according to Embodiment 1 only in the configuration of optical receptacle 320. Therefore, the same components as those of optical module 100 according to Embodiment 1 are denoted by the same reference numerals, and the description thereof is omitted.

### (Configuration of Optical Module)

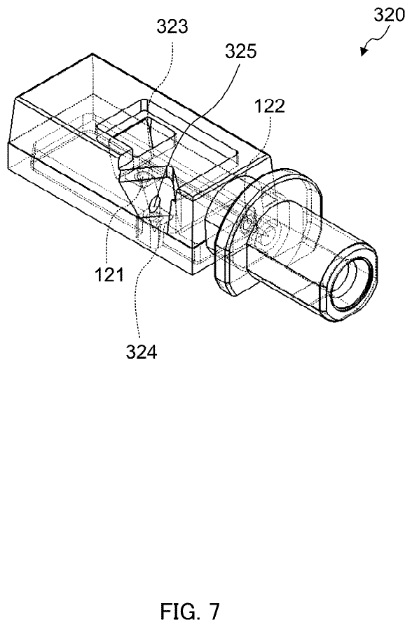

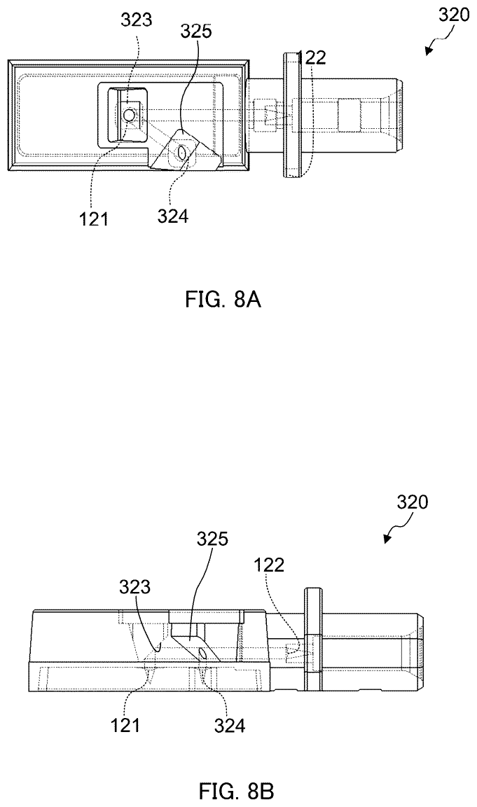

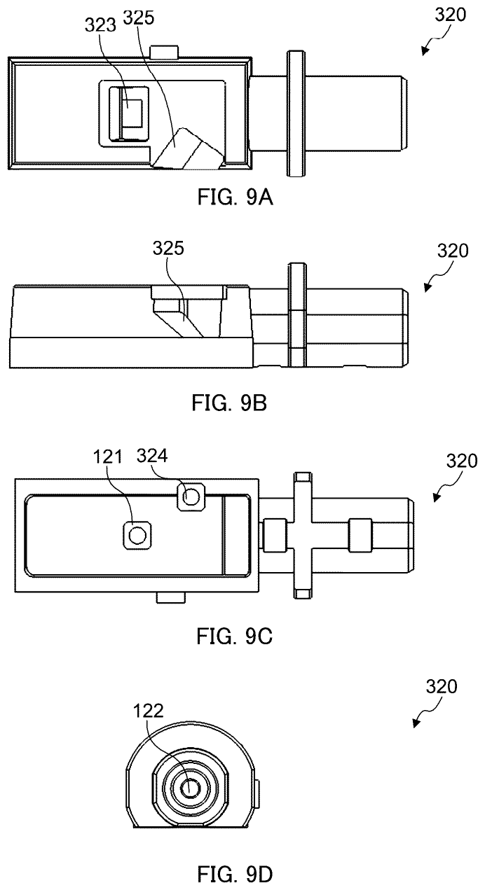

FIG. 7 is a perspective view of optical receptacle 320 according to Embodiment 3. FIG. 8A is a plan view of optical receptacle 320 according to Embodiment 3, and FIG. 8B is a front view of optical receptacle 320. FIG. 9A is a plan view of optical receptacle 320, FIG. 9B is a front view of optical receptacle 320, FIG. 9C is a bottom view of optical receptacle 320, and FIG. 9D is a side view of optical receptacle 320. Note that FIG. 8A corresponds to FIG. 9A, and FIG. 8B corresponds to FIG. 9B. In FIGS. 8A and 8B, the interior configuration and the optical path are illustrated in dotted lines.

The optical module includes photoelectric conversion device 110 and optical receptacle 320. As illustrated in FIGS. 7, 8A, 8B, and 9A to 9D, optical receptacle 320 includes first optical surface 121, second optical surface 122, and diffraction portion 323. In the present embodiment, optical receptacle 320 further includes third optical surface 325 and fourth optical surface 324. In the present embodiment, in optical receptacle 320, first optical surface 121, second optical surface 122, diffraction portion 323, third optical surface 325, and fourth optical surface 324 are integrally formed.

Diffraction portion 323 diffracts a part of the light incident on first optical surface 121 toward optical transmission member 140 as n-th order diffracted light (n=−1, −2, or −3) (signal light), and diffracts another part of the light toward detection element 114 as m-th order diffracted light (m is an integer other than n) (monitor light). Diffraction portion 323 diffracts the n-th order diffracted light and the m-th order diffracted light in respective different directions in a second imaginary plane perpendicular to the optical axis of the light emitted by light emitting element 113 and incident on first optical surface 121. The angle formed between the optical axis of the n-th order diffracted light and the optical axis of the m-th order diffracted light in the second imaginary plane is in the range of 10 to 90 degrees. When the angle is within the above range, the signal light and the monitor light can be separated.

Diffraction portion 323 satisfies following Expressions 1 and 2 when the wavelength of the light incident on first optical surface 121 is denoted by λ, the refractive index of the medium through which the light incident on diffraction portion 323 travels is denoted by N, the period of the blaze shape is denoted by Λ, the incidence angle of the light incident on first optical surface 121 to diffraction portion 323 is denoted by θi, and the reflection diffraction angle to optical transmission member 140 is denoted by θr:

$$[ 1 ]$$

$$sin θ r = ( 1 / N ) \times \{ N \times sin θ i - n \times ( λ / Λ ) \} ; and \qquad ( Expression 1 )$$

$$[ 2 ]$$

$$70 ° \leq θ r + θ i \leq 110 ° . \qquad ( Expression 2 )$$

It is preferable that incidence angle θi satisfy following Expression 4:

$$[ 4 ]$$

$$36 ° \leq θ i \leq 89 ° . \qquad ( Expression 4 )$$

Third optical surface 325 is an optical surface that reflects, toward fourth optical surface 324, the monitor light diffracted by diffraction portion 323. In the present embodiment, the shape of third optical surface 325 is a flat surface. Third optical surface 325 is an inclined surface inclined toward fourth optical surface 324 with decreasing distance to second optical surface 122.

Fourth optical surface 324 causes, to be emitted toward detection element 114, the monitor light reflected by third optical surface 325. Other configurations of fourth optical surface 324 are the same as those of fourth optical surface 124 of Embodiment 1.

Although the result is not particularly illustrated, the optical module of the present embodiment successfully suppressed a decrease in the optical coupling efficiency even when the optical axis of second optical surface 122 or the central axis of optical transmission member 140 is displaced in either of the X direction and the Y direction. Further, it was ascertained that the shape of the spot was not distorted.

### Effects

The optical module according to the present embodiment has the same effect as optical module 100 according to Embodiment 1.

### Embodiment 4

Next, an optical module according to Embodiment 4 will be described. The optical module according to the present embodiment differs from optical module 100 according to Embodiment 1 only in the configuration of optical receptacle 420. Therefore, the same components as those of optical module 100 according to Embodiment 1 are denoted by the same reference numerals, and the description thereof is omitted.

### (Configuration of Optical Module)

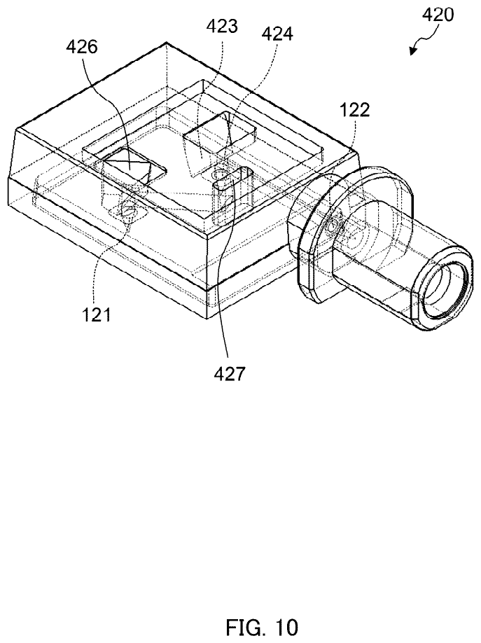

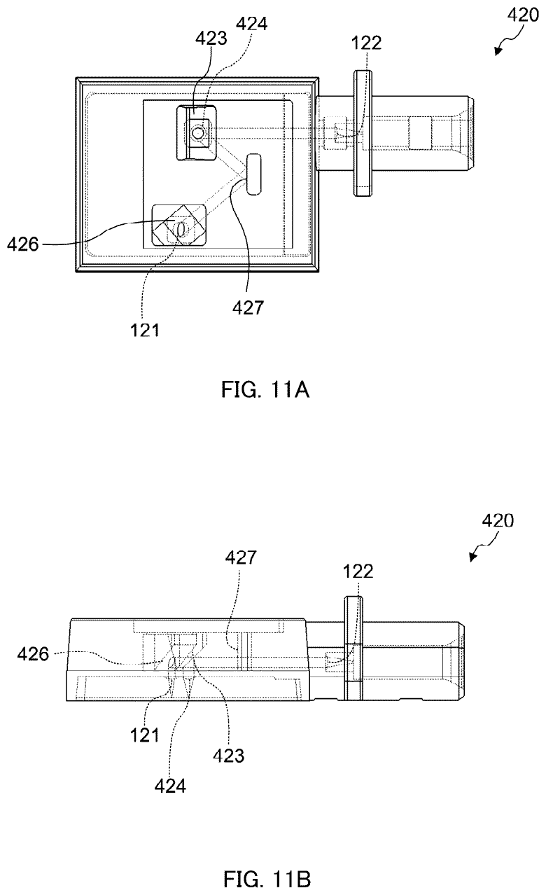

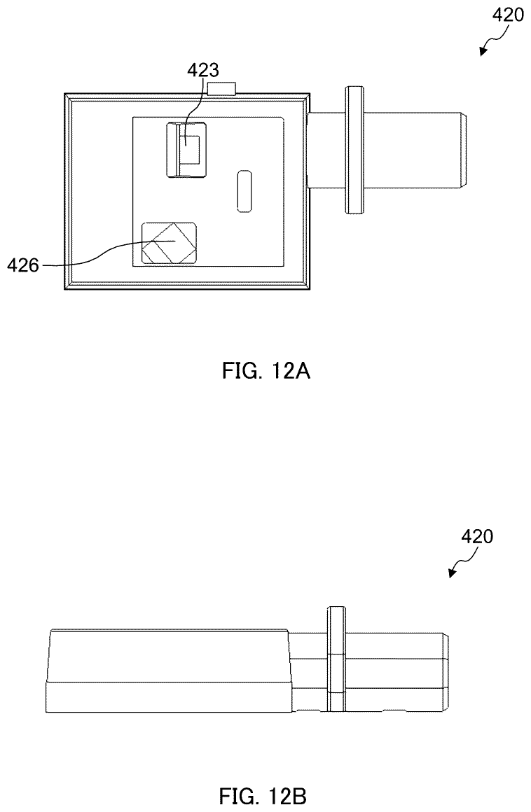

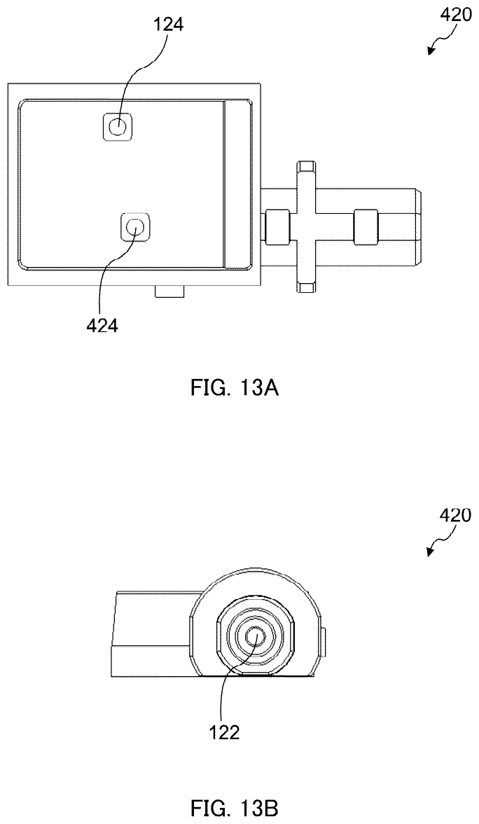

FIG. 10 is a perspective view of optical receptacle 420 according to Embodiment 4 of the present invention. FIG. 11A is a plan view of optical receptacle 420 according to Embodiment 4, and FIG. 11B is a front view of optical receptacle 420. FIG. 12A is a plan view of optical receptacle 420, and FIG. 12B is a front view of optical receptacle 420. FIG. 13A is a bottom view of optical receptacle 420, and FIG. 13B is a side view of optical receptacle 420 of optical receptacle 420. Note that FIG. 11A corresponds to FIG. 12A, and FIG. 11B corresponds to FIG. 12B. In FIGS. 11A and 11B, the interior configuration and the optical path are illustrated in dotted lines.

The optical module includes photoelectric conversion device 110 and optical receptacle 420. As illustrated in FIGS. 10A, 11A, 11B, 12A, 12B, 13A, and 13B, optical receptacle 420 includes first optical surface 121, second optical surface 122, and diffraction portion 423. In the present embodiment, optical receptacle 420 further includes fourth optical surface 424, fifth optical surface 426, and sixth optical surface 427. In the present embodiment, in optical receptacle 420, first optical surface 121, second optical surface 122, diffraction portion 423, fourth optical surface 424, fifth optical surface 426, and sixth optical surface 427 are integrally formed.

Fifth optical surface 426 is an optical surface that reflects, toward sixth optical surface 427, the light incident on first optical surface 121. The shape of fifth optical surface 426 is not particularly limited as long as it can perform the above-described functions. In the present embodiment, fifth optical surface 426 is a flat surface. In the present embodiment, fifth optical surface 426 reflects the light incident on first optical surface 121 by 450 in plan view, and reflects the light incident on first optical surface 121 by 900 in front view.

Sixth optical surface 427 is a reflective surface that reflects the light reflected by fifth optical surface 426 toward diffraction portion 423. The shape of sixth optical surface 427 is not particularly limited as long as it can perform the above-described functions. In the present embodiment, sixth optical surface 427 is a flat surface. In the present embodiment, sixth optical surface 427 reflects, by 900 in plan view, the light reflected by fifth optical surface 426.

Diffraction portion 423 reflects a part of the light reflected by sixth optical surface 427 toward optical transmission member 140 as n-th order diffracted light (n=−1, −2, or −3) (signal light), and reflects another part of the light toward detection element 114 as m-th order diffracted light (m is an integer other than n) (monitor light). Diffraction portion 423 reflects the n-th order diffracted light and the m-th order diffracted light in respective different directions in the first imaginary plane including the optical axis of the light emitted by light emitting element 113 and incident on first optical surface 121. The angle formed between the optical axis of the n-th order diffracted light and the optical axis of the m-th order diffracted light in the first imaginary plane is in the range of 10 to 90 degrees. When the angle is within the above range, the signal light and the monitor light can be separated.

Diffraction portion 423 satisfies following Expressions 1 and 2 when the wavelength of the light incident on first optical surface 121 is denoted by λ, the refractive index of the medium through which the light incident on diffraction portion 223 travels is denoted by N, the period of the blaze shape is denoted by Λ, the incidence angle of the light incident on first optical surface 121 to diffraction portion 423 is denoted by θi, and the reflection diffraction angle to optical transmission member 140 is denoted by θr:

$$[ 1 ]$$

$$sin θ r = ( 1 / N ) \times \{ N \times sin θ i - n \times ( λ / Λ ) \} ; and \qquad ( Expression 1 )$$

$$[ 2 ]$$

$$70 ° \leq θ r + θ i \leq 110 ° . \qquad ( Expression 2 )$$

It is preferable that incidence angle θi satisfy following Expression 4:

$$[ 4 ]$$

$$36 ° \leq θ i \leq 89 ° . \qquad ( Expression 4 )$$

Although the result is not particularly illustrated, the optical module of the present embodiment successfully suppressed a decrease in the optical coupling efficiency even when the optical axis of second optical surface 122 or the central axis of optical transmission member 140 is displaced in either of the X direction and the Y direction. Further, it was ascertained that the shape of the spot was not distorted.

### Effects

The optical module according to the present embodiment has the same effect as optical module 100 according to Embodiment 1.

### Embodiment 5

Next, an optical module according to Embodiment 5 will be described. The optical module according to the present embodiment differs from optical module 100 according to Embodiment 1 only in the configuration of optical receptacle 520. Therefore, the same components as those of optical module 100 according to Embodiment 1 are denoted by the same reference numerals, and the description thereof is omitted.

### (Configuration of Optical Module)

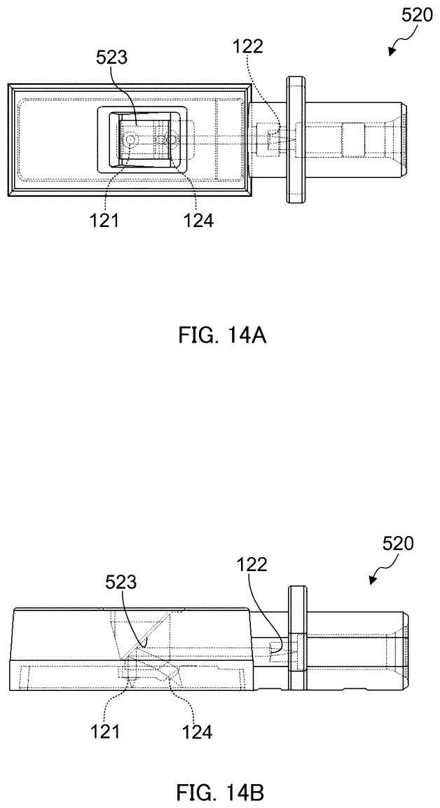

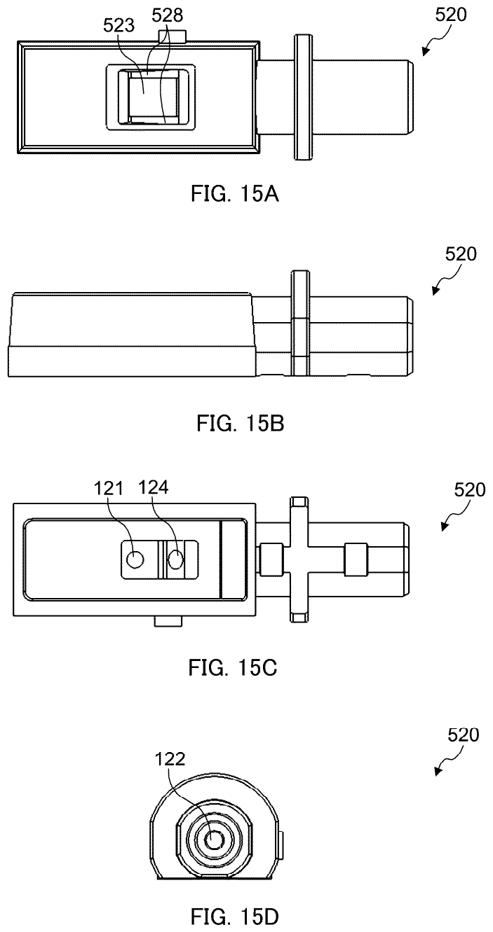

FIG. 14A is a plan view of optical receptacle 520 according to Embodiment 4, and FIG. 14B is a front view of optical receptacle 520. FIG. 15A is a plan view of optical receptacle 120, FIG. 15B is a front view of optical receptacle 520, FIG. 15C is a bottom view of optical receptacle 520, and FIG. 15D is a side view of optical receptacle 520. Note that FIG. 14A corresponds to FIG. 15A, and FIG. 14B corresponds to FIG. 15B. In FIGS. 14A and 14B, the interior configuration and the optical path are illustrated in dotted lines.

The optical module includes photoelectric conversion device 110 and optical receptacle 520. As illustrated in FIGS. 14A and 15A to 15D, optical receptacle 520 includes first optical surface 121, second optical surface 122, and diffraction portion 523. In the present embodiment, optical receptacle 520 further includes fourth optical surface 124 and placement portion 528. With respect to optical receptacle 520 in the present embodiment, diffraction portion 523 is formed separately from first optical surface 121, second optical surface 122, and placement portion 528. Further, with respect to optical receptacle 520, first optical surface 121, second optical surface 122, and fourth optical surface 124 are integrally formed, and only diffraction portion 523 is formed as a separate body.

Diffraction portion 523 diffracts a part of the light incident on first optical surface 121 toward optical transmission member 140 as n-th order diffracted light (n=−1, −2, or −3) (signal light), and diffracts another part of the light to detection element 114 as m-th order diffracted light (m is an integer other than n) (monitor light). The material of diffraction portion 523 is not particularly limited as long as it can perform the above-described functions because diffraction portion 523 is formed separately from first optical surface 121, second optical surface 122, and fourth optical surface 124. Exemplary materials for diffraction portion 523 include transparent resins such as polyether imides (PEI) (e.g., ULTEM (registered trademark)) and cyclic olefinic resins and glasses.

Diffraction portion 523 diffracts the n-th order diffracted light (−3rd order diffracted light in the present embodiment) and the m-th order diffracted light (0th order diffracted light in the present embodiment) in respective different directions in the first imaginary plane including the optical axis of the light emitted by light emitting element 113 and incident on first optical surface 121.

Diffraction portion 523 satisfies following Expressions 1 and 2 when the wavelength of the light incident on first optical surface 121 is denoted by λ, the refractive index of the medium through which the light incident on diffraction portion 523 travels is denoted by N, the period of the blaze shape is denoted by Λ, the incidence angle of the light incident on first optical surface 121 to diffraction portion 523 is denoted by θi, and the reflection diffraction angle to optical transmission member 140 is denoted by θr:

$$[ 1 ]$$

$$sin θ r = ( 1 / N ) \times \{ N \times sin θ i - n \times ( λ / Λ ) \} ; and \qquad ( Expression 1 )$$

$$[ 2 ]$$

$$70 ° \leq θ r + θ i \leq 110 ° . \qquad ( Expression 2 )$$

In the present embodiment, diffraction portion 523 is formed separately from first optical surface 121 and second optical surface 122, and thus, the medium through which the light incident on diffraction portion 523 travels becomes air (air layer). Therefore, refractive index N of the medium through which the light incident on diffraction portion 523 travels is 1. It is preferable that incidence angle θi satisfy following Expression 4:

$$[ 4 ]$$

$$36 ° \leq θ i \leq 89 ° . \qquad ( Expression 4 )$$

Diffraction portion 523 is disposed on placement portion 528. The configuration of placement portion 528 is not particularly limited as long as it can perform the above-described functions. In the present embodiment, placement portion 528 supports diffraction portion 523 at an outer edge portion.

In the optical module according to the present embodiment, the light emitted by light emitting element 113 enters the inside of optical receptacle 520 at first optical surface 121. Then, after being emitted to the outside, the light reaches diffraction portion 523. The n-th order diffracted light separated by diffraction portion 523 enters the inside of optical receptacle 520 again and then reaches second optical surface 122. The m-th order diffracted light enters the inside of optical receptacle 520 again and then reaches fourth optical surface 124.

Although the result is not particularly illustrated, the optical module of the present embodiment successfully suppressed a decrease in the optical coupling efficiency even when the optical axis of second optical surface 122 or the central axis of optical transmission member 140 is displaced in either of the X direction and the Y direction. Further, it was ascertained that the shape of the spot was not distorted.

### Effects

The optical module according to the present embodiment has the same effect as optical module 100 according to Embodiment 1.

In the present embodiment as well, diffraction portion 523 may diffract the n-th order diffracted light and the m-th order diffracted light in respective different directions in the second imaginary plane perpendicular to the optical axis of the light emitted by light emitting element 113 and incident on first optical surface 121.

### Embodiment 6

Next, an optical module according to Embodiment 6 will be described. The optical module according to the present embodiment differs from optical module 100 according to Embodiment 1 only in the configuration of optical receptacle 620. Therefore, the same components as those of optical module 100 according to Embodiment 1 are denoted by the same reference numerals, and the description thereof is omitted.

### (Configuration of Optical Module)

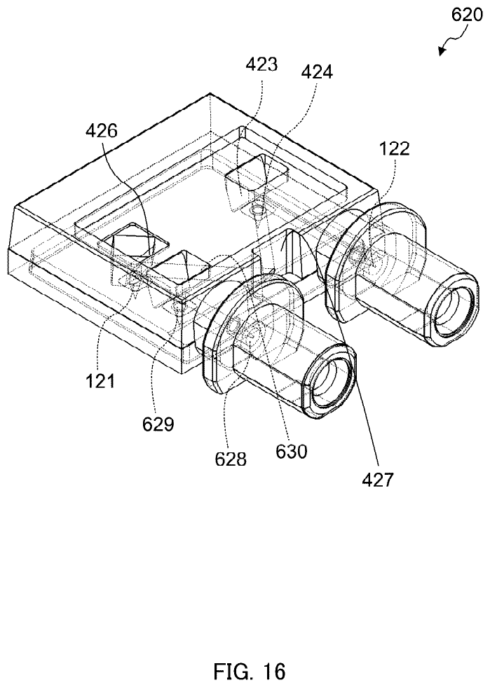

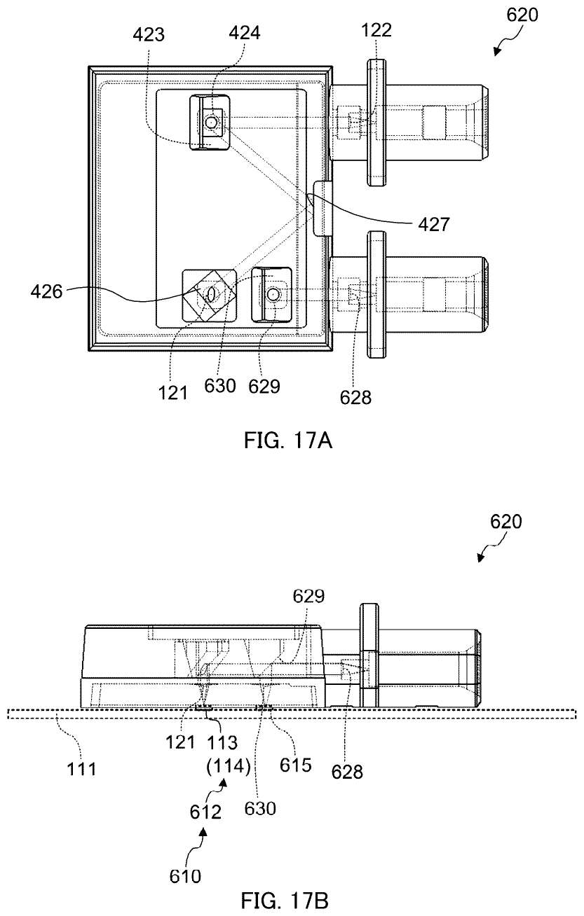

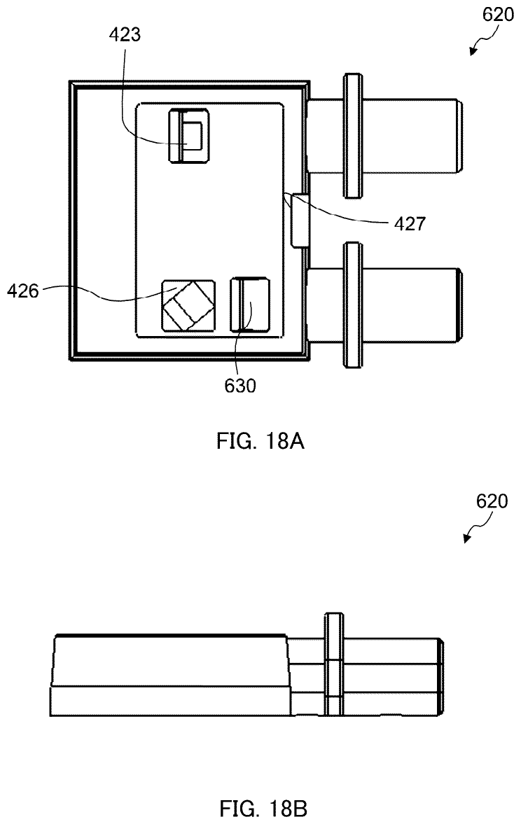

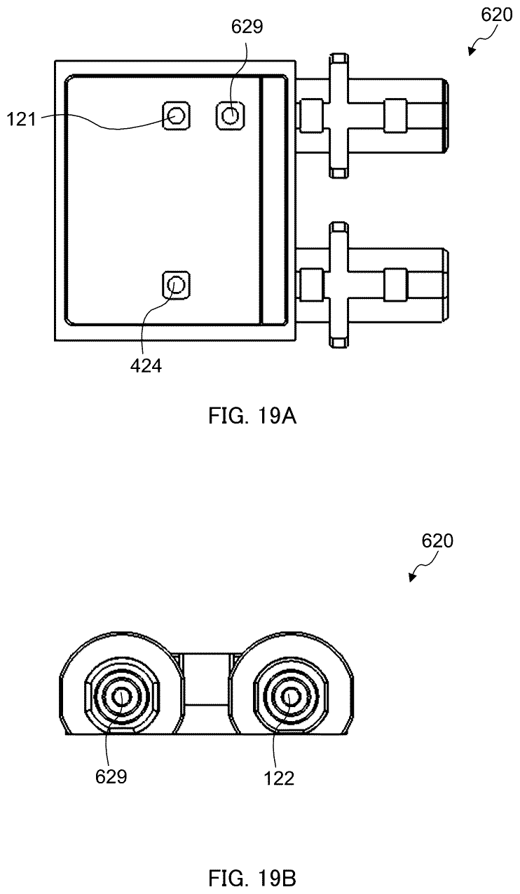

FIG. 16 is a perspective view of optical receptacle 620 according to Embodiment 6. FIG. 17A is a plan view of optical receptacle 620 according to Embodiment 6, and FIG. 17B is a front view of optical receptacle 620. FIG. 18A is a plan view of optical receptacle 620, and FIG. 18B is a front view of optical receptacle 620. FIG. 19A is a bottom view and FIG. 19B is a side view. Note that FIG. 17A corresponds to FIG. 18A, and FIG. 17B corresponds to FIG. 18B. In FIGS. 17A and 17B, the interior configuration and the optical path are illustrated in dotted lines.

The optical module includes photoelectric conversion device 610 and optical receptacle 620. The optical module according to the present embodiment is an optical module for transmission and reception. Photoelectric conversion device 610 includes substrate 111 and photoelectric conversion element 612. In the present embodiment, the optical module is an optical module for transmission and reception, and accordingly, photoelectric conversion element 612 is light emitting element 113, detection element 114, and light receiving element 615. Light receiving element 615 is, for example, a photodetector. In the present embodiment, the light emitting surface of light emitting element 113, the detection surface of detection element 114, and the light receiving surface of light receiving element 615 are disposed to be parallel to one another.

In the present embodiment, optical receptacle 620 emits a part of the light emitted by photoelectric conversion element 612 (light emitting element 113) toward the end surface of optical transmission member 140, and emits another part of the light toward detection element 114. Further, light emitted from the end surface of optical transmission member 140 is emitted toward photoelectric conversion element 612 (light receiving element 615).

Optical receptacle 620 includes first optical surface 121, second optical surface 122, and diffraction portion 423. In the present embodiment, optical receptacle 620 further includes fourth optical surface 424, fifth optical surface 426, sixth optical surface 427, seventh optical surface 628, eighth optical surface 629, and ninth optical surface 630. In optical receptacle 620 in the present embodiment, it is preferable that first optical surface 121, second optical surface 122, diffraction portion 423, fourth optical surface 424, fifth optical surface 426, sixth optical surface 427, seventh optical surface 628, eighth optical surface 629, and ninth optical surface 630 are integrally formed. Accordingly, the number of parts can be reduced.

Diffraction portion 423, fourth optical surface 424, fifth optical surface 426, and sixth optical surface 427 are the same as those of optical receptacle 420 according to Embodiment 4, and thus description thereof will be omitted.

Diffraction portion 423 satisfies following Expressions 1 and 2 when the wavelength of the light incident on first optical surface 121 is denoted by λ, the refractive index of the medium through which the light incident on diffraction portion 223 travels is denoted by N, the period of the blaze shape is denoted by Λ, the incidence angle of the light incident on first optical surface 121 to diffraction portion 423 is denoted by θi, and the reflection diffraction angle to optical transmission member 140 is denoted by θr:

$$[ 1 ]$$

$$sin θ r = ( 1 / N ) \times \{ N \times sin θ i - n \times ( λ / Λ ) \} ; and \qquad ( Expression 1 )$$

$$[ 2 ]$$

$$70 ° \leq θ r + θ i \leq 110 ° . \qquad ( Expression 2 )$$

It is preferable that incidence angle θi satisfy following Expression 4:

$$[ 4 ]$$

$$36 ° \leq θ i \leq 89 ° . \qquad ( Expression 4 )$$

Seventh optical surface 628 is an optical surface that allows, to enter the inside of optical receptacle 620, light (reception light) emitted from the end surface of optical transmission member 140. The shape of seventh optical surface 628 is not particularly limited as long as it can perform the above-described functions. The shape of seventh optical surface 628 may be a flat surface, a convex lens surface convex toward the end surface of optical transmission member 140, or a concave lens surface concave toward optical transmission member 140. In the present embodiment, the shape of seventh optical surface 628 is a convex lens surface that is convex toward the end surface of optical transmission member 140. It is preferable that the central axis of seventh optical surface 628 coincide with the optical axis of the light emitted from optical transmission member 140.

Eighth optical surface 629 is an optical surface that causes, to be emitted toward light receiving element 615, light incident on seventh optical surface 628. The shape of eighth optical surface 629 is not particularly limited. The shape of eighth optical surface 629 may be a flat surface, a convex lens surface convex toward the light receiving surface of light receiving element 615, or a concave lens surface concave toward the light receiving surface of light receiving element 615. In the present embodiment, the shape of eighth optical surface 629 is a convex lens surface that is convex toward the light receiving surface of light receiving element 615. It is preferable that the central axis of eighth optical surface 629 coincide with the center of the light receiving surface of light receiving element 615.

Ninth optical surface 630 reflects the light incident on seventh optical surface 628 toward eighth optical surface 629. The shape of ninth optical surface 630 is not particularly limited as long as it can perform the above-described functions. In the present embodiment, ninth optical surface 630 is a flat surface. Ninth optical surface 630 is an inclined surface that approaches eighth optical surface 629 with increasing distance from seventh optical surface 628.

In the optical module according to the present embodiment, the light emitted by light emitting element 113 is emitted toward optical transmission member 140 and detection element 114 as in Embodiment 1.

Further, the light emitted from the end surface of optical transmission member 140 enters the inside of optical receptacle 620 at seventh optical surface 628. Next, the light incident on optical receptacle 620 is reflected by ninth optical surface 630, and is emitted to the outside of optical receptacle 620 at eighth optical surface 629 toward photoelectric conversion element 612 (light receiving element 615). The light emitted from eighth optical surface 629 to the outside of optical receptacle 620 reaches photoelectric conversion element 612 (light receiving element 615) while converging.

Although the result is not particularly illustrated, the optical module of the present embodiment successfully suppressed a decrease in the optical coupling efficiency even when the optical axis of second optical surface 122 or the central axis of optical transmission member 140 is displaced in either of the X direction and the Y direction. Further, it was ascertained that the shape of the spot was not distorted.

### Effects

The optical module according to the present embodiment has the same effect as optical module 100 according to Embodiment 1.

### Embodiment 7

Next, optical module 700 according to Embodiment 7 will be described. Optical module 700 according to the present embodiment differs from optical module 100 according to Embodiment 1 only in the configuration of optical receptacle 720. Therefore, the same components as those of optical module 100 according to Embodiment 1 are denoted by the same reference numerals, and the description thereof is omitted.

### (Configuration of Optical Module and Optical Receptacle)

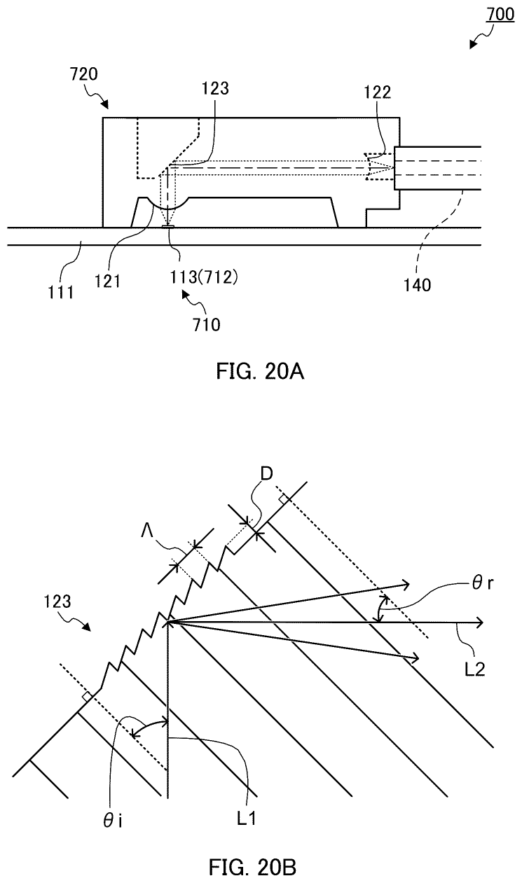

FIG. 20A is a front view of optical module 700 according to Embodiment 7, and FIG. 20B is a sectional view of diffraction portion 123. In FIGS. 20A and 20B the interior configuration and the optical path are illustrated in dotted lines.

As illustrated in FIG. 20A, optical module 700 includes photoelectric conversion device 710 including photoelectric conversion element 712 and optical receptacle 720. In the present embodiment, photoelectric conversion element 712 of photoelectric conversion device 710 is light emitting element 113. That is, photoelectric conversion element 712 of the present embodiment is different from photoelectric conversion device 110 of Embodiment 1 in that it does not include detection element 114.

Optical receptacle 720 includes first optical surface 121, second optical surface 122, and diffraction portion 123. That is, optical receptacle 720 of the present embodiment is different from optical receptacle 120 of Embodiment 1 in that it does not include fourth optical surface 124.

First optical surface 121 allows incidence of light emitted by light emitting element 113.

Second optical surface 122 is an optical surface that causes a part of the light incident on first optical surface 121 to be emitted toward the end surface of optical transmission member 140.

As illustrated in FIGS. 20A and 20B, diffraction portion 123 is a reflective diffraction grating that diffracts at least a part of the light incident on first optical surface 121 as n-th order diffracted light (n=−1, −2, or −3) (signal light) toward optical transmission member 140. The n-th order diffracted light is the −1st order diffracted light, the −2nd order diffracted light, or the −3rd order diffracted light. Diffraction portion 123 has a blaze shape.

Diffraction portion 123 satisfies following Expressions 1 and 2 when the wavelength of the light incident on first optical surface 121 is denoted by λ, the refractive index of the medium through which the light incident on diffraction portion 123 travels is denoted by N, the period of the blaze shape is denoted by Λ, the incidence angle of the light incident on first optical surface 121 to diffraction portion 123 is denoted by θi, and the reflection diffraction angle to optical transmission member 140 is denoted by θr:

$$[ 1 ]$$

$$sin θ r = ( 1 / N ) \times \{ N \times sin θ i - n \times ( λ / Λ ) \} ; and \qquad ( Expression 1 )$$

$$[ 2 ]$$

$$70 ° \leq θ r + θ i \leq 110 ° . \qquad ( Expression 2 )$$

It is preferable that incidence angle θi satisfy following Expression 4:

$$[ 4 ]$$

$$36 ° \leq θ i \leq 89 ° . \qquad ( Expression 4 )$$

As described above, wavelength k of the light incident on first optical surface 121 is in the range of 0.85 to 1.67 μm. In the present embodiment, the medium through which the light incident on diffraction portion 123 travels is a resin, and thus, refractive index N thereof is in the range of 1.44 to 1.65.

As illustrated in FIG. 20B, incidence angle θi of the light incident on first optical surface 121 to diffraction portion 123 is the angle of the light incident on first optical surface 121 with respect to the normal to the surface on which diffraction portion 123 is disposed. Since the light incident on first optical surface 121 needs to be reflected by diffraction portion 123, incidence angle θi is an angle equal to or larger than the critical angle with respect to the surface of diffraction portion 123 on which the light incident on first optical surface 121 is incident. In the present embodiment, the angle of the light incident on first optical surface 121 with respect to the surface of diffraction portion 123 on which the light incident on first optical surface 121 is incident is in the range of 36 to 89 degrees, and preferably in the range of 38 to 60 degrees.

Further, as illustrated in FIG. 20B, reflection diffraction angle θr to optical transmission member 140 is the angle of the n-th order diffracted light (n=−1, −2, or −3) with respect to the normal to the surface on which diffraction portion 123 is disposed. Reflection diffraction angle θr is obtained by above Expression 1. Reflection diffraction angle θr is in the range of 1 to 54 degrees and preferably in the range of 30 to 52 degrees because incidence angle θi is 36 to 89 degrees.

Therefore, the sum of incidence angle θi and reflection diffraction angle θr (corresponding to above Expression 2) is in the range of 37 to 143 degrees, preferably in the range of 70 to 110 degrees. Further, incidence angle θi and reflection diffraction angle θr may satisfy following Expression 3:

$$[ 3 ]$$

$$θ r + θ i = 90 ° . \qquad ( Expression 3 )$$

As illustrated in FIG. 20B, the angle formed by first straight line L1 connecting the center point of light emitting element 113 and the arrival point at diffraction portion 123 where the center of the light flux from light emitting element 113 arrives, and second linear L2 connecting the arrival point and the center point at the end portion of optical transmission member 140 is preferably the same angle as the sum of the incidence angle and the reflection diffraction angle.

As illustrated in FIG. 20B, diffraction portion 123 has a blaze shape. Period A of the blaze shape needs to be larger than wavelength k of the incident light in order to cause the 1st order diffraction. Meanwhile, in a resonance region in which period A of the blaze shape is equal to or less than 4 to 5 times of wavelength k of the light incident on diffraction portion 123, characteristics greatly change depending on the difference in the shape and size of diffraction portion 123, and thus the practicality is low. Therefore, it is preferable that, for stable use even taking into consideration a production error, period A of the blaze shape be used in a scalar region of about 10 times wavelength k of the light incident on diffraction portion 123. Specifically, it is preferable that when used at a wavelength of 0.85 m, period A of the blaze shape be in the range of 3 to 30 m, preferably in the range of 5 to 15 km.

Depth D of the blaze shape is not particularly limited. It preferable that depth D of the blaze shape be within a range of 200 to 1,500 nm.

### (Simulation 1)

The diffraction efficiency of the n-th order diffracted light varies depending on depth D of the blaze shape. Therefore, the relationship between depth D of the blaze shape and the diffraction efficiency was simulated. The relationship between depth D of the blaze shape and the diffraction efficiencies can be derived from the Maxwell's equation called Rigorous Coupled Wave Analysis (RCWA) method. The RCWA method is described, for example, in Journal of the Optical Society of America Vol. 73, Issue 4, pp. 451-455 (1983). Here, incidence angle θi of the light incident on diffraction portion 123 was set to 450 and reflection diffraction angle θr was set to 45°. Refractive index N of optical receptacle 720 was 1.6315.

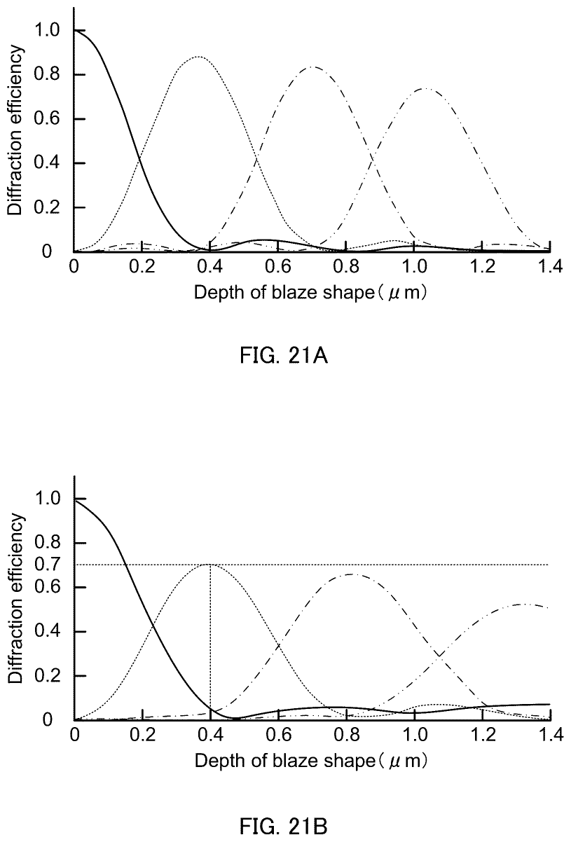

FIG. 21A is a graph illustrating the relation between diffraction efficiency of the n-th order diffracted light calculated by the RCWA method and depth D of the blaze shape. The horizontal axis in FIG. 21A indicates depth D (m) of the blaze shape, and the vertical axis indicates the diffraction efficiency. The diffraction efficiency on the vertical axis is expressed as a ratio to the 0th order diffracted light. The solid line in FIG. 21A illustrates the result of the 0th order diffracted light, the dotted line illustrates the result of the −1st order diffracted light, the dashed-dotted line illustrates the result of the −2nd order diffracted light, and the double-dot dashed line illustrates the result of the −3rd order diffracted light.

As illustrated in FIG. 21A, it can be seen that the −1st order diffracted light, the −2nd order diffracted light, and the −3rd order diffracted light appear in this order along a direction from lower to higher depth D of the blaze shape. Further, it can be seen that the diffraction efficiency varies depending on depth D of the blaze shape. Furthermore, it can be seen that the diffraction efficiency decreases as the order of the diffracted light increases.

In order to further attenuate the intensity of the light emitted by light emitting element 113 and sent to optical transmission member 140, it is necessary to use higher-order diffracted light. That is, it is understood that in order to further attenuate the intensity of the light sent to optical transmission member 140, it is preferable to use −2nd order diffracted light rather than −1st order diffracted light and −3rd order diffracted light rather than the −2nd order diffracted light. In addition, it can be seen that in the case of using high-order diffracted light, depth D of the blaze shape needs to be increased.

Here, since the diffraction efficiency changes according to depth D of the blaze shape, it seems that depth D of the blaze shape may be set so as to satisfy a desired attenuation amount. However, in practice, a production error of about ±0.002 m is caused for depth D of the blaze shape. Therefore, it is preferable that a depth at which the absolute value of ΔE (minute change amount of diffractive efficiency)/AD (minute change amount of depth of the blaze shape) is small be employed for depth D of the blaze shape. For this purpose, it is preferable to employ depth D of the blaze shape which maximizes the diffraction efficiency, or to select the higher-order diffracted light having a gentle curve to be described later. Note that, it is possible to appropriately determine depending on the attenuation amount whether depth D of the blaze shape with the maximum diffraction efficiency is employed or the higher-order diffracted light with a gentle curve to be described later is selected.

### (Simulation 2)

A simulation was conducted for the case where incidence angle θi is 42°. Here, diffraction efficiency E was set to 0.70 (attenuation amount is 30%). When incidence angle θi is 42°, reflection diffraction angle θr is 48°. Wavelength λ of the incident light was set to 0.85 m, period Λ of the blaze shape was set to 7 μm, and refractive index N of the optical receptacle was set to 1.636. In this case, the reflection diffraction angle of the −2nd order diffracted light is Ang(R(−2))=54.88°.

FIG. 21B is a graph illustrating the relation between depth D of the blaze shape and the diffraction efficiency of the n-th order diffracted light calculated by the RCWA method when the incidence angle θi is 42°. The horizontal axis in FIG. 21B indicates depth D (μm) of the blaze shape, and the vertical axis indicates the diffraction efficiency. The diffraction efficiency on the vertical axis is expressed as a ratio to the 0th order diffracted light. The solid line in FIG. 21B illustrates the result of the 0th order diffracted light, the dotted line illustrates the result of the −1st order diffracted light, the dashed-dotted line illustrates the result of the −2nd order diffracted light, and the double-dot dashed line illustrates the result of the −3rd order diffracted light.

As illustrated in FIG. 21B, when desired diffraction efficiency E is 0.70, the diffracted light used is the −1st order diffracted light. In addition, it can be seen that largest diffraction efficiency E by diffraction portion 123 calculated by the RCWA method is 0.70, and depth D of the blaze shape when the −1st order diffracted light is used is preferably 0.40 m.

### (Simulation 3)

A simulation was conducted for the case where incidence angle θi is 39°. Here, diffraction efficiency E was set to 0.658 (attenuation amount was 34.2%). When incidence angle θi is 39°, reflection diffraction angle θr is 51.09°. Wavelength λ of the incident light was set to 0.85 μm, period Λ of the blaze shape was set to 7 μm, and refractive index N of the optical receptacle was set to 1.636.

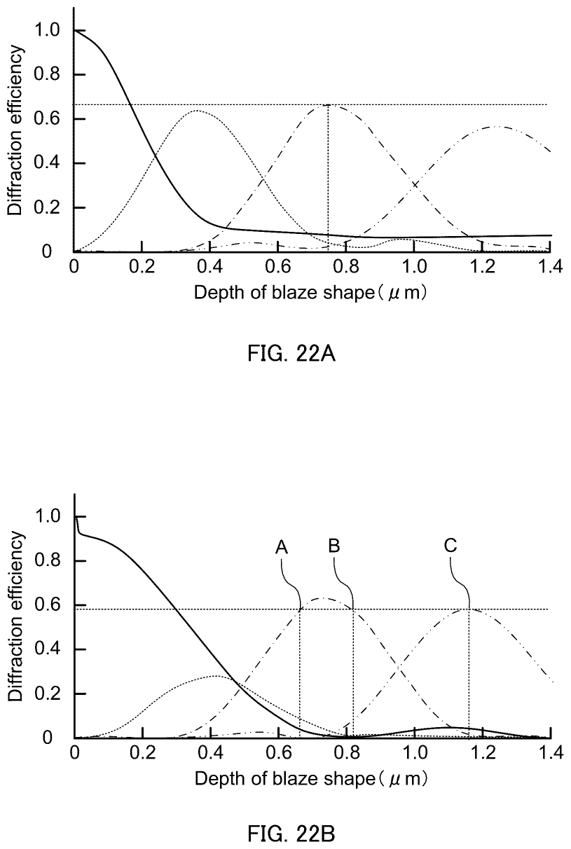

FIG. 22A is a graph illustrating the relation between depth D of the blaze shape and the diffraction efficiency of the n-th order diffracted light calculated by the RCWA method when the incidence angle θi is 39°. The horizontal axis in FIG. 22A indicates depth D (μm) of the blaze shape, and the vertical axis indicates the diffraction efficiency. The diffraction efficiency on the vertical axis is expressed as a ratio to the 0th order diffracted light. The solid line in FIG. 22A illustrates the result of the 0th order diffracted light, the dotted line illustrates the result of the −1st order diffracted light, the dashed-dotted line illustrates the result of the −2nd order diffracted light, and the double-dot dashed line illustrates the result of the −3rd order diffracted light.

As illustrated in FIG. 22A, when desired diffraction efficiency E is 0.658 (attenuation amount is 34.2%), the diffracted light to be used is the −2nd order diffracted light. In addition, it can be seen that largest diffraction efficiency E by diffraction portion 123 calculated by the RCWA method is 0.658, and depth D of the blaze shape when the −2nd order diffracted light is used is preferably 0.76 μm.

### (Simulation 4)

A simulation was conducted for the case where incidence angle θi is 36°. Here, diffraction efficiency E was set to 0.584 (attenuation amount is 41.6%). When incidence angle θi is 36°, reflection diffraction angle θr is 54.19°. Wavelength λ of the incident light was set to 0.85 μm, period Λ of the blaze shape was set to 7 μm, and refractive index N of the optical receptacle was set to 1.636.

FIG. 22B is a graph illustrating the relation between depth D of the blaze shape and the diffraction efficiency of the n-th order diffracted light calculated by the RCWA method when the incidence angle θi is 36°. The horizontal axis in FIG. 22B indicates depth D (μm) of the blaze shape, and the vertical axis indicates the diffraction efficiency. The diffraction efficiency on the vertical axis is expressed as a ratio to the 0th order diffracted light. The solid line in FIG. 22B illustrates the result of the 0th order diffracted light, the dotted line illustrates the result of the −1st order diffracted light, the dashed-dotted line illustrates the result of the −2nd order diffracted light, and the double-dot dashed line illustrates the result of the −3rd order diffracted light.

As illustrated in FIG. 22B, when desired diffraction efficiency E is 0.584 (attenuation amount is 41.6%), the −2nd order diffracted light and −3rd order diffracted light can be used. At this time, possible depth D of the blaze shape is 0.66 m (−2nd order diffracted light) at point A, 0.82 μm (−2nd order diffracted light) at point B, or 1.14 μm (−3rd order diffracted light) at point C. Absolute value A1 of the slope of the curve corresponding to the −2nd order diffracted light at point A where depth D of the blaze shape is 0.66 μm is +10.2. Absolute value B1 of the slope of the curve corresponding to the −2nd order diffracted light at point B where depth D of the blaze shape is 0.82 μm is +1.02. Absolute value C1 of the slope of the curve corresponding to the −3rd order diffracted light at point C where depth D of the blaze shape is 1.14 m is −1.2. Here, the smallest absolute value among absolute value A1, absolute value B1, and absolute value C1 is absolute value C1. Therefore, it is understood that the use of the −3rd order diffracted light is preferable, and depth D of the blaze shape of 1.14 μm is preferable at this time, taking into consideration the production error of depth D of the blaze shape.

Although the result is not particularly illustrated, the optical module of the present embodiment successfully suppressed a decrease in the optical coupling efficiency even when the optical axis of second optical surface 122 or the central axis of optical transmission member 140 is displaced in either of the X direction and the Y direction. Further, it was ascertained that the shape of the spot was not distorted.

### Effects

The optical module according to the present embodiment has the same effect as optical module 100 according to Embodiment 1.

This application is entitled to and claims the benefit of Japanese Patent Application No. 2022-030192, filed on Feb. 28, 2022. The disclosure of the specification and drawings is incorporated herein by reference in its entirety.

### INDUSTRIAL APPLICABILITY

The optical receptacle and the optical module according to the present invention are useful for optical communication using an optical transmission member.

### REFERENCE SIGNS LIST

100 Optical module
110, 610, 710 Photoelectric conversion device
111 Substrate
112, 612, 712 Photoelectric conversion element
113 Light emitting element
114 Detection element
120, 220, 320, 420, 520, 620, 720 Optical receptacle
121 First optical surface
122 Second optical surface
123, 223 Diffraction portion
124, 224, 324 Fourth optical surface
125, 225, 325 Third optical surface
140 Optical transmission member
141 Ferrule
426 Fifth optical surface
427 Sixth optical surface
628 Seventh optical surface
629 Eighth optical surface
630 Ninth optical surface
615 Light receiving element

1. An optical receptacle that is disposed between an optical transmission member and a photoelectric conversion device including a light emitting element, the optical receptacle being configured to optically connect the light emitting element and the optical transmission member to each other, the optical receptacle comprising:
a first optical surface for allowing incidence of light emitted by the light emitting element;
a second optical surface for causing, to be emitted toward the optical transmission member, the light incident on the first optical surface and traveling inside the optical receptacle; and
a diffraction portion including a blaze shape and configured to diffract at least a part of the light incident on the first optical surface as n-th order diffracted light (n=−1, −2, or −3) toward the optical transmission member, wherein
the diffraction portion satisfies following Expressions 1 and 2 when a wavelength of the light incident on the first optical surface is denoted by λ, a refractive index of a medium through which the light incident on the diffraction portion travels is denoted by N, a period of the blaze shape is denoted by Λ, an incidence angle at which the light incident on the first optical surface is incident on the diffraction portion is denoted by θi, and a reflection diffraction angle to the optical transmission member is denoted by θr:
$$[ 1 ]$$
$$sin θ r = ( 1 / N ) \times \{ N \times sin θ i - n \times ( λ / Λ ) \} ; and \qquad ( Expression 1 )$$
$$[ 2 ]$$
$$70 ° \leq θ r + θ i \leq 110 ° . \qquad ( Expression 2 )$$

2. The optical receptacle according to claim 1, wherein
an angle formed by a first straight line and a second straight line is identical to a sum of the incidence angle and the reflection diffraction angle, the first straight line connecting a center point of the light emitting element and an arrival point at the diffraction portion where a center of a light flux from the light emitting element arrives, the second straight line connecting the arrival point and a center point at an end portion of the optical transmission member.

3. The optical receptacle according to claim 1, wherein:
the photoelectric conversion device further includes a detection element, and
the diffraction portion diffracts at least a part of the light incident on the first optical surface as m-th order diffracted light (m is an integer other than n) toward the detection element.

4. The optical receptacle according to claim 1, wherein
the first optical surface, the second optical surface, and the diffraction portion are integrally formed.

5. The optical receptacle according to claim 1, wherein
the diffraction portion is formed separately from the first optical surface and the second optical surface.

6. The optical receptacle according to claim 3, wherein
the diffraction portion diffracts the n-th order diffracted light and the m-th order diffracted light in respective different directions in a first imaginary plane including an optical axis of the light emitted by the light emitting element and incident on the first optical surface.

7. The optical receptacle according to claim 3, wherein
the diffraction portion diffracts the n-th order diffracted light and the m-th order diffracted light in respective different directions in a second imaginary plane perpendicular to an optical axis of the light emitted by the light emitting element and incident on the first optical surface.

8. The optical receptacle according to claim 3, further comprising:
a third optical surface between the diffraction portion and the detection element, the third optical surface being configured to reflect, toward the detection element, light diffracted by the diffraction portion.

9. The optical receptacle according to claim 1, wherein
following Expression 3 is further satisfied:
$$[ 3 ]$$
$$θ r + θ i = 90 ° . \qquad ( Expression 3 )$$

10. The optical receptacle according to claim 1, wherein
a depth of the blaze shape is a depth which maximizes diffraction efficiency of the diffraction portion calculated by a Rigorous Coupled Wave Analysis (RCWA) method.

11. The optical receptacle according to claim 1, wherein
a depth of the blaze shape is a depth of the blaze shape at which an absolute value of a slope of a curve that indicates a relation between the depth of the blaze shape and the diffraction efficiency and that is obtained for each diffracted light by a Rigorous Coupled Wave Analysis (RCWA) method is the smallest among absolute values of slopes of a plurality of the curves for a predetermined diffraction efficiency.

12. An optical module, comprising:
a photoelectric conversion device including a light emitting element; and
an optical receptacle disposed between the photoelectric conversion device and an optical transmission member and configured to optically connect the light emitting element and the optical transmission member to each other, wherein
the optical receptacle includes:
a first optical surface for allowing incidence of light emitted by the light emitting element,
a second optical surface for causing, to be emitted toward the optical transmission member, the light incident on the first optical surface and traveling inside the optical receptacle, and
a diffraction portion including a blaze shape and configured to diffract at least a part of the light incident on the first optical surface as n-th order diffracted light (n=−1, −2, or −3) toward the optical transmission member,
the diffraction portion satisfies following Expressions 1 and 4 when a wavelength of the light incident on the first optical surface is denoted by λ, a refractive index of a medium through which the light incident on the diffraction portion travels is denoted by N, a period of the blaze shape is denoted by Λ, an incidence angle at which the light incident on the first optical surface is incident on the diffraction portion is denoted by θi, and a reflection diffraction angle to the optical transmission member is denoted by θr, and
an angle formed by a first straight line and a second straight line is identical to a sum of the incidence angle and the reflection diffraction angle, the first straight line connecting a center point of the light emitting element and an arrival point at the diffraction portion where a center of a light flux from the light emitting element arrives, the second straight line connecting the arrival point and a center point at an end portion of the optical transmission member:
$$[ 1 ]$$
$$sin θ r = ( 1 / N ) \times \{ N \times sin θ i - n \times ( λ / Λ ) \} ; and \qquad ( Expression 1 )$$
$$[ 4 ]$$
$$36 ° \leq θ i \leq 89 ° . \qquad ( Expression 4 )$$

13. The optical module according to claim 12, wherein
the photoelectric conversion device further includes a detection element.
